(19) United States
(12) Patent Application Publication
(10) Pub. No.: US 2026/0206162 A1
(43) Pub. Date: Jul. 16, 2026

(54) LOCKING DEVICE AND TERMINAL DEVICE

(71) Applicant: Fulian Precision Electronics (Tianjin) Co., LTD., Tianjin (CN)

(72) Inventors: WEN-LING CHIANG, New Taipei (TW); Hsiao-Hsuan Chang, New Taipei (TW)

(21) Appl. No.: 19/217,032

(22) Filed: May 23, 2025

(30) Foreign Application Priority Data
Jan. 14, 2025 (CN) 202510057845.2

(51) Int. Cl. H05K 7/14

(52) U.S. Cl. CPC H05K 7/1402; H05K 7/1485

(57) ABSTRACT

A locking device can lock with a component having a slot. The locking device includes a fixing member, a sliding assembly, a driving member, and a second elastic member. The fixing member includes a sliding groove being slidably connected to component. The sliding assembly includes a blocking member, a first elastic member, and a sliding block. The blocking member can extend into the sliding groove and be engaged with the slot. The first elastic member can deform to disengage the blocking member from the slot. The sliding block can move to enable the blocking member and the first elastic member to move. The driving member can drive the sliding assembly to move. The second elastic member can deform to return the sliding assembly to an original position after the sliding assembly moves. The present disclosure further provides a terminal device.

### FIELD

The subject matter herein generally relates to locking technologies, and more particularly, to a locking device and a terminal device.

### BACKGROUND

Circuit boards need to be detachably locked in servers. The circuit boards typically need to be manually pushed into or pulled out of the servers, which is difficult for users to operate due to the limited space in the servers. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view of a terminal device according to an embodiment of the present disclosure.

FIG. 2 is an exploded view of a locking device of the terminal device shown in FIG. 1.

FIG. 3 is similar to the FIG. 2, but showing the locking device viewed from another angle.

FIG. 4 is a cross-sectional view of the terminal device shown in FIG. 1 along line A-A.

FIG. 5 is a cross-sectional view of the terminal device shown in FIG. 1 along line B-B.

FIG. 6 is a diagrammatic view showing a component separated from the locking device of the terminal device shown in FIG. 1.

FIG. 7 is a diagrammatic view showing the component in FIG. 6 sliding into a sliding groove of the locking device.

FIG. 8 is a diagrammatic view showing a blocking member of the locking device in FIG. 7 engaged with a slot of the component.

FIG. 9 is a diagrammatic view showing a rotation of a driving member of the locking device in FIG. 8 to unlock the locking device.

FIG. 10 is a diagrammatic view showing the blocking member disengaging from the slot after rotating the driving member shown in FIG. 8.

FIG. 11 is a top view showing the blocking member engaged with the slot in FIG. 8.

FIG. 12 is a top view showing the blocking member disengaged from the slot in FIG. 10.

FIG. 13 is a top view of a partial area of the terminal device according to other embodiments of the present disclosure.

FIG. 14 is a top view showing a second inclined surface of the blocking member in contact with a first inclined surface of the fixing member shown in FIG. 13.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

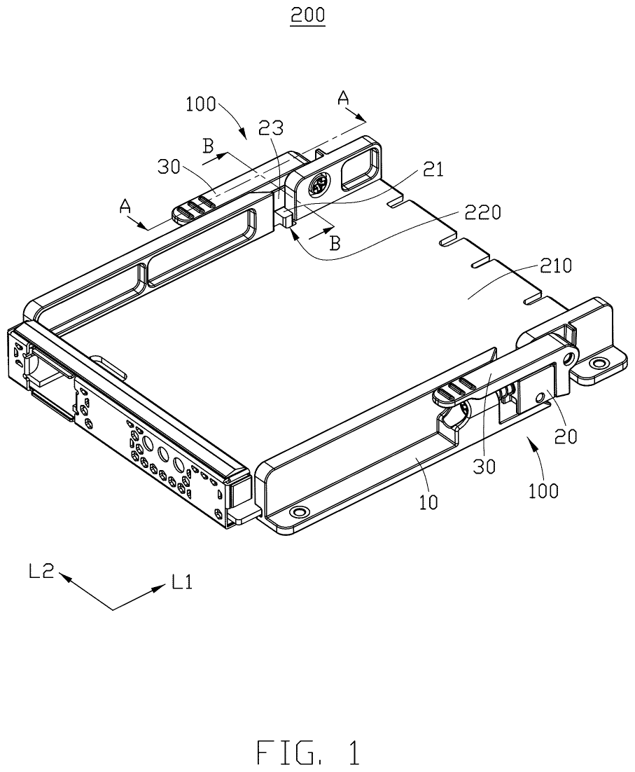

Referring to FIG. 1, a terminal device 200 is provided according to an embodiment of the present disclosure. The terminal device 200 includes at least one locking device 100 and a component 210. The locking device 100 can detachably be engaged with the component 210 having a slot 220. The locking device 100 has locking, unlocking, and resetting functions. The terminal device 200 may be a server, and the component 210 may be a circuit board, such as an OCP (Open Compute Project) card.

In the embodiment, the terminal device 200 includes two locking devices 100. The two terminal devices 200 are arranged on both sides of the component 210. In other embodiments, the number of locking devices 100 is not limited.

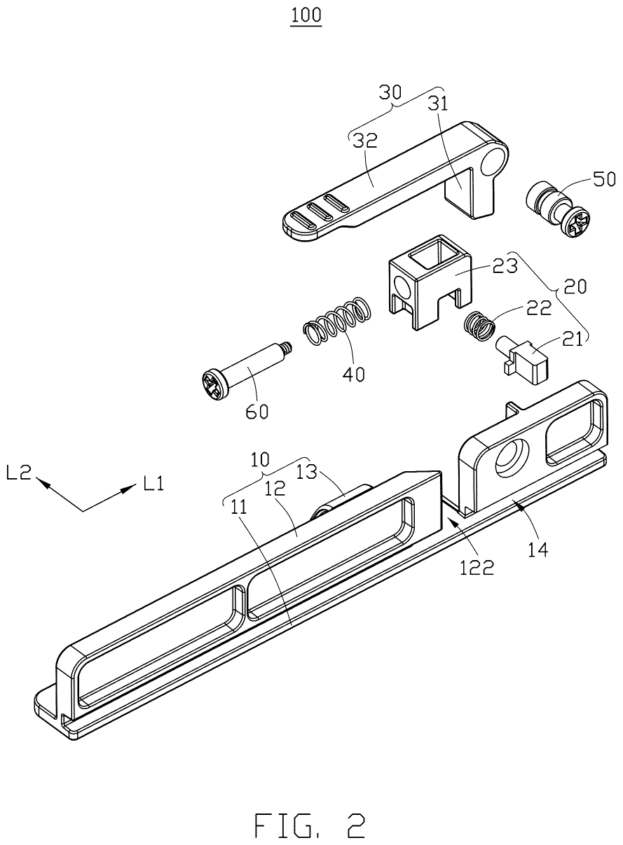

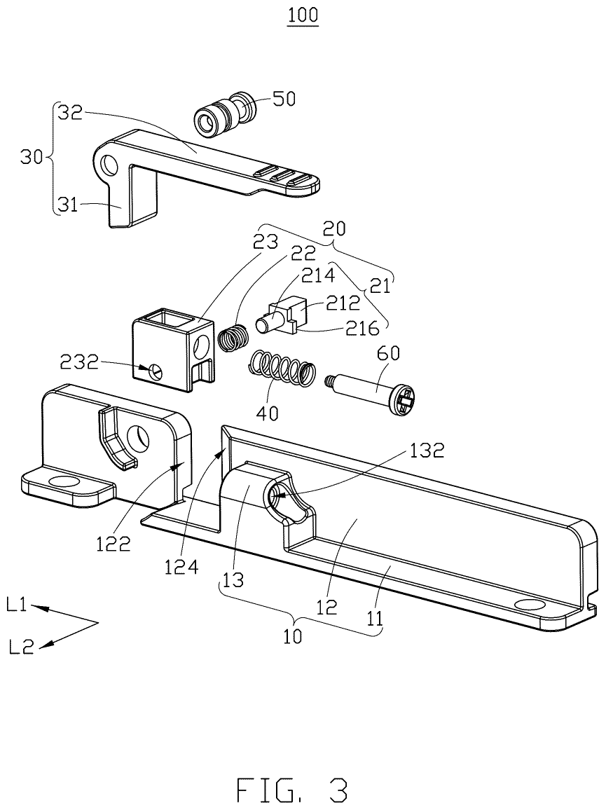

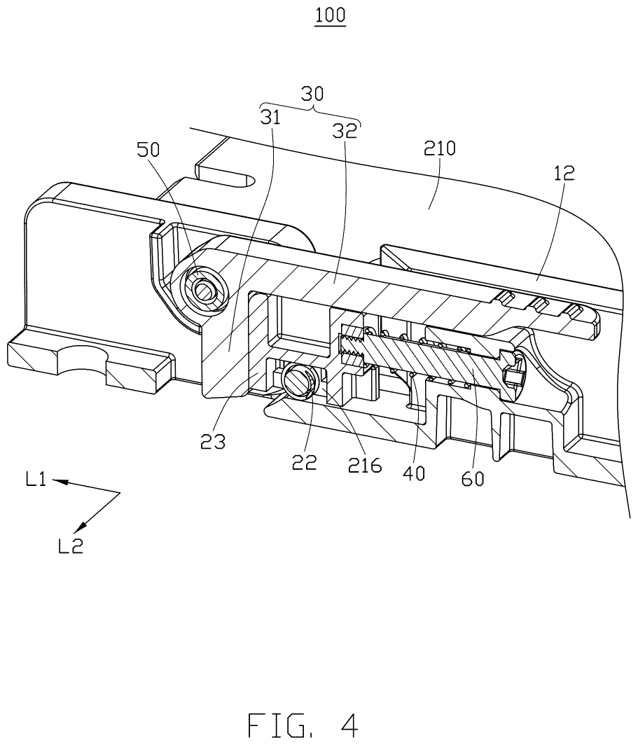

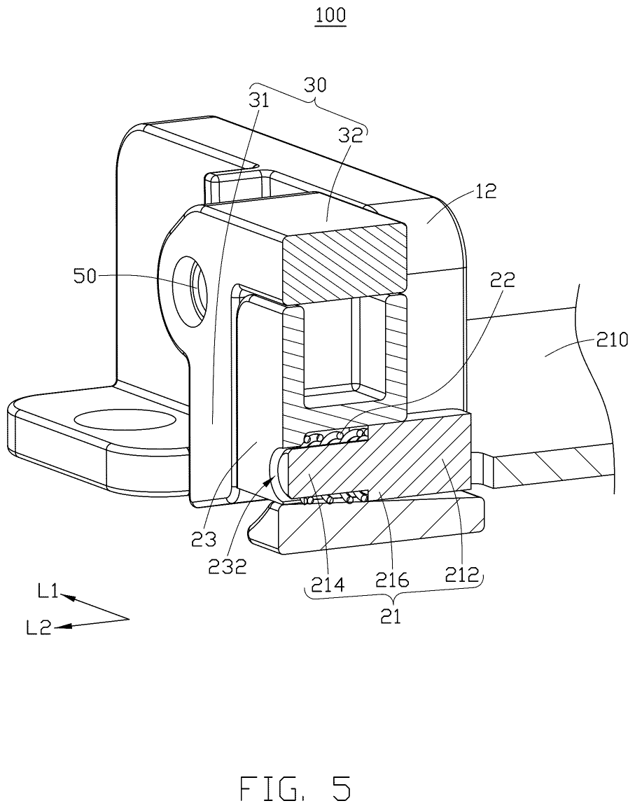

Referring to FIGS. 2, 3, 4, and 5, each locking device 100 may include a fixing member 10, a sliding assembly 20, a driving member 30, and a second elastic member 40.

The fixing member 10 may include a supporting portion 11 and a blocking portion 12. The supporting portion 11 and the blocking portion 12 both extend along a first direction L1. The supporting portion 11 extends from both sides of the blocking portion 12 along a second direction L2. A sliding groove 14 is formed between the supporting portion 11 and one side of the blocking portion 12. The sliding groove 14 can allow the component 210 to slide along the sliding groove 14 in the first direction L1.

The sliding assembly 20 may include a blocking member 21, a first elastic member 22, and a sliding block 23. The first elastic member 22 connects the blocking member 21 to the sliding block 23. The blocking member 21 can extend into the sliding groove 14 along the second direction L2 and be engaged with the slot 220. The first direction L1 intersects with the second direction L2. In the embodiment, the first direction L1 is perpendicular to the second direction L2. The first elastic member 22 can deform along the second direction L2 to disengage the blocking member 21 from the slot 220. The sliding block 23 can move along the first direction L1 to enable the blocking member 21 and the first elastic member 22 to move along the first direction L1. The driving member 30 is connected to the sliding assembly 20 and can drive the sliding assembly 20 to move along the first direction L1. The second elastic member 40 is connected to the sliding assembly 20 and can deform along the first direction L1 to return the sliding assembly 20 to its original position after the sliding assembly 20 moves along the first direction L1.

When the component 210 slides along the sliding groove 14 in first direction L1, the component 210 abuts against the blocking member 21 extending into the sliding groove 14. The blocking member 21 compresses the first elastic member 22 along the second direction L2 and moves along the second direction L2. The component 210 continues to slide along the first direction L1 until the blocking member 21 aligns with the slot 220. The blocking member 21 moves toward and is engaged with the slot 220 under the elastic force of the first elastic member 22, thereby locking the component 210 by the locking device 100.

When the component 210 needs to be unlocked, an external force is applied to the driving member 30. The driving member 30 drives the sliding assembly 20 to move along the first direction L1. The blocking member 21 simultaneously moves along the first direction L1 and then abuts against the fixing member 10 to move along the second direction L2, and is disengaged from the slot 220 to release the component 210. After the sliding assembly 20 moves along the first direction L1 and compresses the second elastic member 40, when the force applied to the driving member 30 is removed, the second elastic member 40 rebounds to drive the sliding assembly 20 to the original position.

The blocking portion 12 may include a through slot 122 and a first inclined surface 124. The through slot 122 communicates with the sliding groove 14. The first inclined surface 124 is one surface forming the through slot 122. The first inclined surface 124 intersects with the first direction L1 and the second direction L2. The first inclined surface 124 faces away from the sliding groove 14.

The blocking member 21 includes a first blocking portion 212, a second blocking portion 214, and a sleeve portion 216. The first blocking portion 212 and the sleeve portion 216 are arranged along the second direction L2. The first blocking portion 212 extends through the through slot 122 into the sliding groove 14. The sleeve portion 216 is located on the side of the first blocking portion 212 away from the sliding groove 14. The sleeve portion 216 surrounds an end of the second blocking portion 214 close to the first blocking portion 212.

When the component 210 is locked to the locking device 100, the surface of the component 210 that first comes into contact with the first blocking portion 212 may be an inclined surface. When the component 210 moves along the first direction L1 and comes into contact with the first blocking portion 212, the component 210 can push the first blocking portion 212 along the second direction L2.

The first elastic member 22 is sleeved on the sleeve portion 216, and two ends of the first elastic member 22 abut against the second blocking portion 214 and the sliding block 23.

The sliding block 23 is provided with a first through hole 232 extending through the sliding block 23 along the second direction L2. The sleeve portion 216 can extend through the first through hole 232. When the blocking member 21 moves relative to the sliding block 23 along the second direction L2, the blocking member 21 compresses the first elastic member 22, causing the first elastic member 22 to deform along the second direction L2.

The driving member 30 can rotate around the second direction L2. The driving member 30 may include a driving portion 31 and a handle 32. The driving portion 31 is fixed on one end of the handle 32 and contacts the sliding block 23. When an external force is applied to the handle 32, the handle 32 rotates and drives the driving portion 31 to rotate synchronously. After the driving portion 31 rotates, the driving portion 31 drives the sliding block 23 to move along the first direction L1.

The locking device 100 may further include a fixed shaft 50. The fixed shaft 50 is fixed on the blocking portion 12 of the fixing member 10 and extends along the second direction L2. The end of the handle 32 with the driving portion 31 is sleeved on the fixed shaft 50. A center axis of the fixed shaft 50 serves as a rotation axis of the driving member 30.

The locking device 100 may further include a pin 60. The second elastic member 40 is sleeved on the pin 60, and two ends of the second elastic member 40 are respectively connected to the fixing member 10 and the sliding block 23. The pin 60 is fixed to one of the fixing member 10 and the sliding block 23, and is movably connected to another one of the fixing member 10 and the sliding block 23, so that when the sliding block 23 moves along the first direction L1, the sliding block 23 can cause the second elastic member 40 to deform along the first direction L1.

In the embodiment, one end of the pin 60 is fixed to the sliding block 23 and movably connected to the fixing member 10. For example, the fixing member 10 further includes a protruding portion 13 located on the side of the blocking portion 12 away from the sliding groove 14. The protruding portion 13 is provided with a second through hole 132 extending through the protruding portion 13 along the first direction L1. The second elastic member 40 is sleeved on the pin 60 and located between the sliding block 23 and the protruding portion 13. One end of the pin 60 is fixed to the sliding block 23 and can movably extend through the second through hole 132.

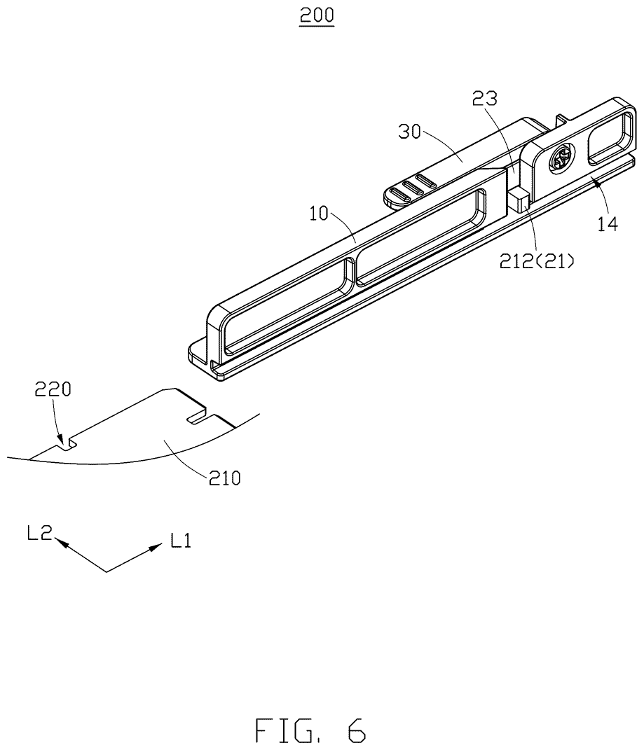

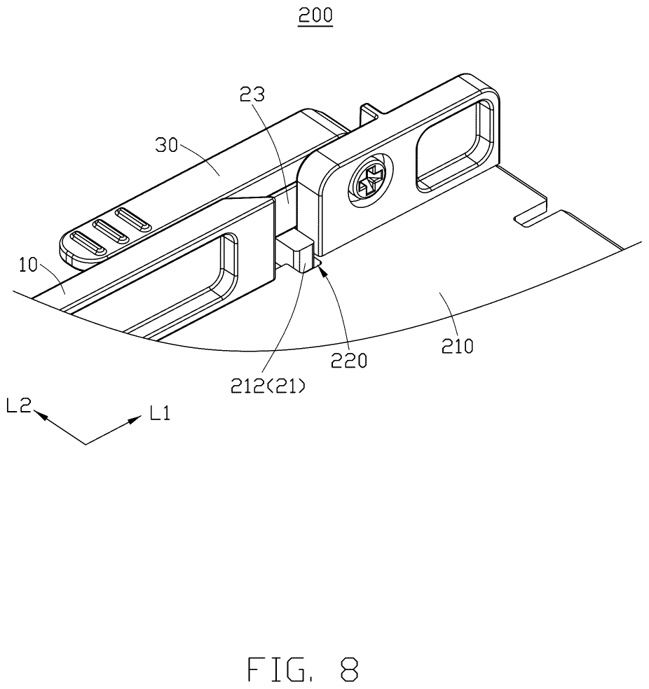

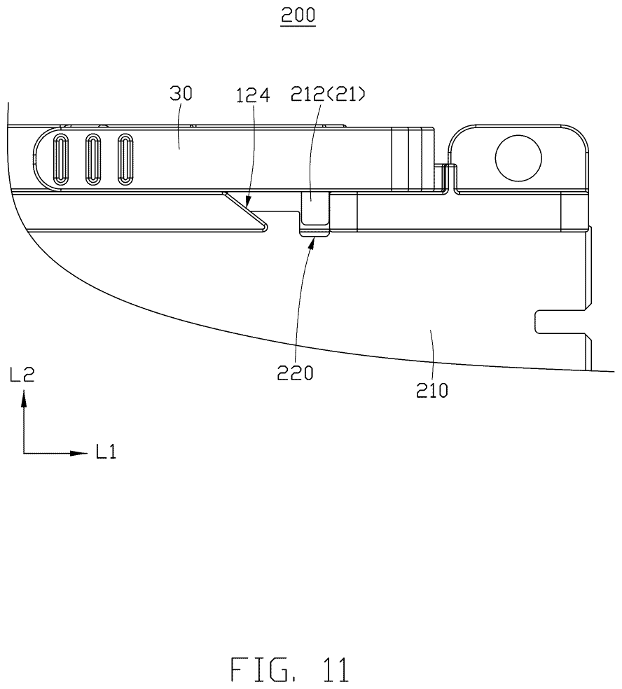

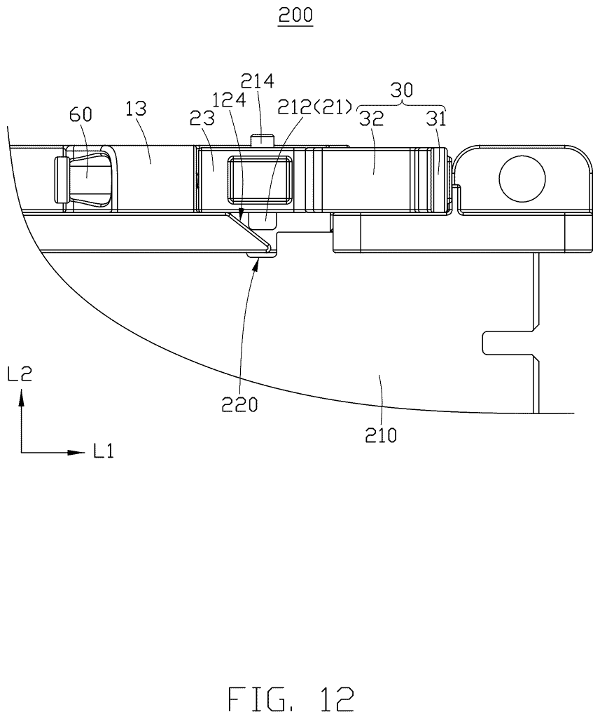

Referring to FIGS. 6 to 12, the relationship between various components of the locking device 100 will be explained through specific operational processes. FIGS. 6 to 8 show the structural schematic views of the locking process of the locking device 100, FIGS. 8 to 10 show the diagrammatic views of the unlocking process of the locking device 100, and FIGS. 11 to 12 show the top views of the unlocking process of the locking device 100.

Referring to FIG. 6, when the component 210 is not placed in the locking device 100, the locking device 100 is in an initial state. The first blocking portion 212 of the blocking member 21 extends into the sliding groove 14, and both the first elastic member 22 and the second elastic member 40 are in their initial states.

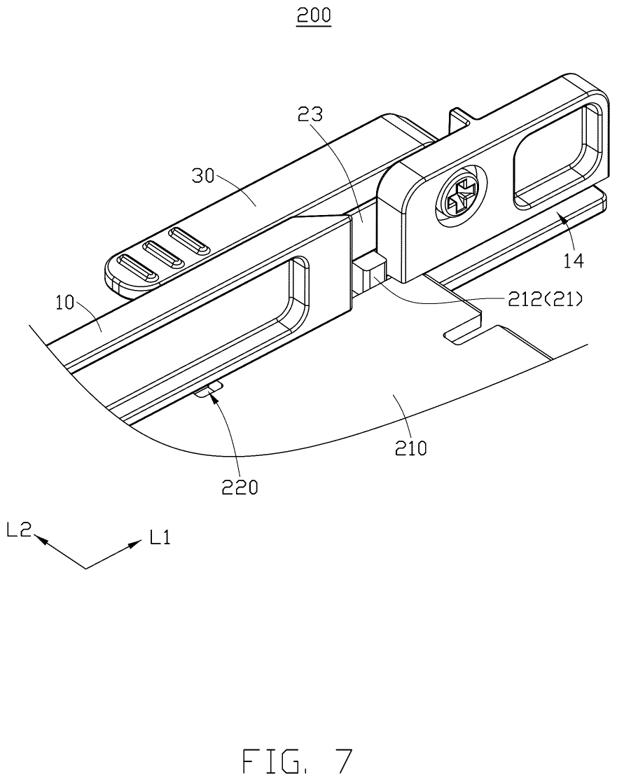

Referring to FIG. 7, when the component 210 needs to be placed in the locking device 100, the side of the component 210 with the slot 220 is placed in the sliding groove 14 and slides along the first direction L1. Then the component 210 comes into contact with the first blocking portion 212. When the component 210 continues to slide along the first direction L1, the component 210 abuts against the first blocking portion 212, causing the blocking member 21 to move along the second direction L2 away from the component 210 and compress the first elastic member 22.

Referring to FIGS. 8 and 11, when the component 210 further slides along the first direction L1 until the first blocking portion 212 aligns with the position of the slot 220, the blocking member 21 moves toward and be engaged with the slot 220 under the elastic force of the first elastic member 22, thereby locking the component 210 by the locking device 100.

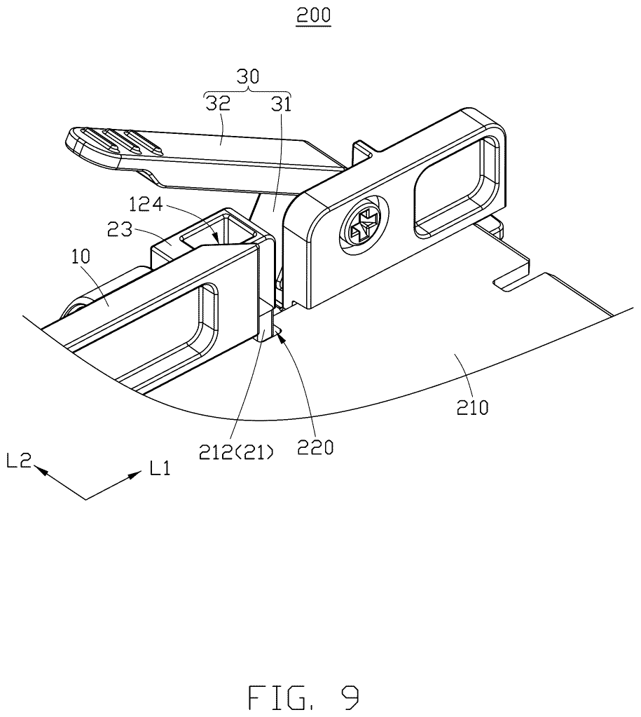

Referring to FIG. 9, when the component 210 needs to be unlocked, the external force is applied to the driving member 30 to rotate the handle 32 around the second direction L2. The driving portion 31 of the driving member 30 rotates synchronously, which drives the sliding block 23 to move along the first direction L1. The first elastic member 22 and the blocking member 21 connected to the sliding block 23 move along the first direction L1 with the sliding block 23, while the sliding block 23 also compresses the second elastic member 40.

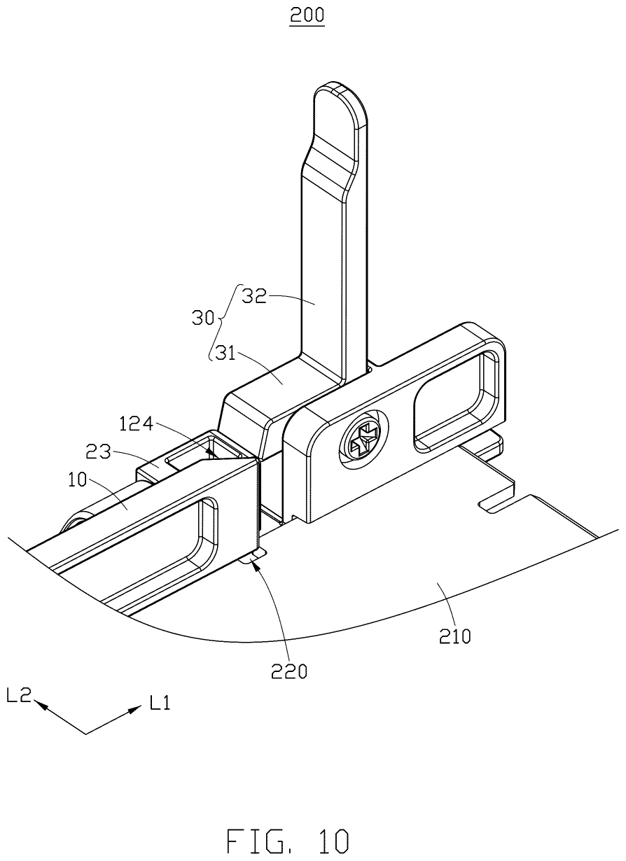

Referring to FIGS. 10 and 12, after the blocking member 21 moves along the first direction L1 until the first blocking portion 212 is in contact with the first inclined surface 124, during the above process, the component 210 moves synchronously along the first direction L1 with the movement of the blocking member 21 (that is, the component 210 can be ejected from the locking device 100). A width of the through slot 122 along the first direction L1 is substantially equal to an ejecting width of the component 210.

When the first blocking portion 212 is in contact with the first inclined surface 124, the first blocking portion 212 is driven to move along the second direction L2 away from the sliding groove 14 and to disengage from the sliding groove 14. The blocking member 21 releases the component 210 and compresses the first elastic member 22, thus the locking device 100 releases the component 210.

After the first blocking portion 212 of the blocking member 21 is disengaged from the slot 220, the external force applied to the driving member 30 can be removed. When the component 210 separates from the locking device 100, the sliding block 23 returns to the original position under the elastic force of the second elastic member 40, and simultaneously, the first elastic member 22 drives the blocking member 21 to return to the original position.

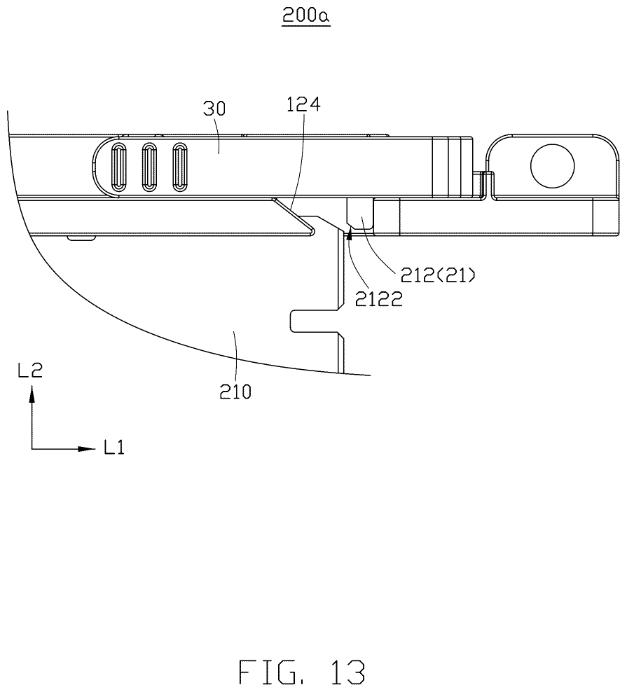

Referring to FIG. 13, another embodiment of the present disclosure further provides a terminal device 200a, which differs from the terminal device 200 in that the first blocking portion 212 of terminal device 200a may include a second inclined surface 2122 located at the end of the first blocking portion 212 away from the sleeve portion 216. The second inclined surface 2122 intersects with the first direction L1 and the second direction L2.

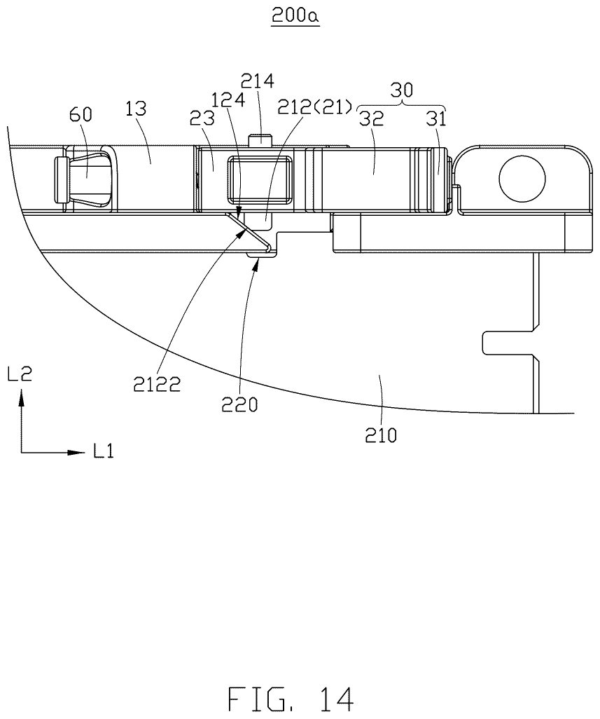

Referring to FIG. 14, during the locking process of the component 210 to the locking device 100, the second inclined surface 2122 can be in contact with the component 210 to facilitate the movement of the first blocking portion 212 along the second direction L2. When the component 210 is unlocked from the locking device 100, the second inclined surface 2122 can be in contact with the first inclined surface 124 to facilitate the movement of the first blocking portion 212 along the second direction L2.

The locking device 100 provided by the embodiments of the present disclosure allows the component 210 to be locked into the locking device 100 by simply pushing the component 210 along the first direction L1. When the component 210 needs to be unlocked, the driving member 30 is rotated to allow the component 210 to be ejected from the locking device 100, and then the component 210 can be pulled out. The assembly and disassembly processes of the component 210 are simple, the locking device 100 can automatically be return to the original sate, and the volume of the locking device 100 is small.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A locking device configured to lock with a component having a slot, the locking device comprising:
a fixing member comprising a sliding groove extending along a first direction, the sliding groove configured to slidably connected to the component so that the component is slidable in the sliding groove along the first direction;
a sliding assembly comprising:
a blocking member configured to extend into the sliding groove along a second direction and engage with the slot;
a first elastic member connected to the blocking member and configured to deform along the second direction to disengage the blocking member from the slot; and
a sliding block connected to the blocking member and the first elastic member, when the sliding block moving along the first direction, the blocking member and the first elastic member driven to move along the first direction;
a driving member connected to the sliding assembly and configured to drive the sliding assembly to move along the first direction; and
a second elastic member connected to the sliding assembly, when the second elastic member deforming along the first direction, the sliding assembly returning to an original position after the sliding assembly moves along the first direction.

2. The locking device of claim 1, wherein the fixing member comprises a first inclined surface intersecting with each of the first direction and the second direction; the blocking member comprises a first blocking portion configured to extend into the sliding groove along the second direction and engage with the slot, and the first inclined surface is configured to be in contact with the component and being drive the first blocking portion to move along the second direction.

3. The locking device of claim 2, wherein the first blocking portion comprises a second inclined surface intersecting with each of the first direction and the second direction, and the second inclined surface is configured to be in contact with the first inclined surface and being drive the first blocking portion to move along the second direction, or second inclined surface is configured to be in contact with the component and being drive the first blocking portion to move along the second direction.

4. The locking device of claim 2, wherein the blocking member further comprises a second blocking portion and a sleeve portion, the first blocking portion and the sleeve portion are arranged along the second direction, the sleeve portion is located on a side of the first blocking portion away from the sliding groove, the sleeve portion surrounds an end of the second blocking portion close to the first blocking portion; the first elastic member is sleeved on the sleeve portion, and two ends of the first elastic member abut against the second blocking portion and the sliding block, respectively.

5. The locking device of claim 4, wherein the sliding block is provided with a first through hole, the first through hole extends through the sliding block along the second direction, and the sleeve portion is configured to extend through the first through hole.

6. The locking device of claim 2, wherein the fixing member is provided with a through slot communicating with the sliding groove, a surface defined by the through slot is the first inclined surface, and the first blocking portion extends through the through slot.

7. The locking device of claims 1, wherein the driving member comprises a driving portion and a handle, the driving portion is located at one end of the handle, the driving portion contacts the sliding block, and the driving portion is configured to rotate with the handle and drive the sliding block to move along the first direction.

8. The locking device of claim 7, further comprising a pin, wherein the second elastic member is sleeved on the pin, two ends of the second elastic member are respectively connected to the fixing member and the sliding block, the pin is fixed to one of the fixing member and the sliding block, and is movably connected to another one of the fixing member and the sliding block.

9. The locking device of claim 8, wherein the fixing member is provided with a second through hole, the second through hole extends through the fixing member along the first direction, and one end of the pin is fixed to the sliding block and configured to movably extend through the second through hole.

10. A terminal device comprising:
a component having a slot;
a locking device comprising:
a fixing member comprising a sliding groove extending along a first direction, the sliding groove configured to slidably connected to the component so that the component is slidable in the sliding groove along the first direction;
a sliding assembly comprising:
a blocking member configured to extend into the sliding groove along a second direction and engage with the slot;
a first elastic member connected to the blocking member and configured to deform along the second direction to disengage the blocking member from the slot; and
a sliding block connected to the blocking member and the first elastic member, when the sliding block moving along the first direction, the blocking member and the first elastic member driven to move along the first direction;
a driving member connected to the sliding assembly and configured to drive the sliding assembly to move along the first direction; and
a second elastic member connected to the sliding assembly, when the second elastic member deforming along the first direction, the sliding assembly returning to an original position after the sliding assembly moves along the first direction;
wherein the locking device is detachably engaged with the slot.

11. The terminal device of claim 10, wherein the fixing member comprises a first inclined surface intersecting with each of the first direction and the second direction; the blocking member comprises a first blocking portion configured to extend into the sliding groove along the second direction and engage with the slot, and the first inclined surface is configured to be in contact with the component and being drive the first blocking portion to move along the second direction.

12. The terminal device of claim 11, wherein the first blocking portion comprises a second inclined surface intersecting with each of the first direction and the second direction, and the second inclined surface is configured to be in contact with the first inclined surface and being drive the first blocking portion to move along the second direction, or second inclined surface is configured to be in contact with the component and being drive the first blocking portion to move along the second direction.

13. The terminal device of claim 11, wherein the blocking member further comprises a second blocking portion and a sleeve portion, the first blocking portion and the sleeve portion are arranged along the second direction, the sleeve portion is located on a side of the first blocking portion away from the sliding groove, the sleeve portion surrounds an end of the second blocking portion close to the first blocking portion; the first elastic member is sleeved on the sleeve portion, and two ends of the first elastic member abut against the second blocking portion and the sliding block, respectively.

14. The terminal device of claim 13, wherein the sliding block is provided with a first through hole, the first through hole extends through the sliding block along the second direction, and the sleeve portion is configured to extend through the first through hole.

15. The terminal device of claim 11, wherein the fixing member is provided with a through slot communicating with the sliding groove, a surface defined by the through slot is the first inclined surface, and the first blocking portion extends through the through slot.

16. The terminal device of claims 10, wherein the driving member comprises a driving portion and a handle, the driving portion is located at one end of the handle, the driving portion contacts the sliding block, and the driving portion is configured to rotate with the handle and drive the sliding block to move along the first direction.

17. The terminal device of claim 16, wherein the terminal device further comprises a pin, the second elastic member is sleeved on the pin, two ends of the second elastic member are respectively connected to the fixing member and the sliding block, the pin is fixed to one of the fixing member and the sliding block, and is movably connected to another one of the fixing member and the sliding block.

18. The terminal device of claim 17, wherein the fixing member is provided with a second through hole, the second through hole extends through the fixing member along the first direction, and one end of the pin is fixed to the sliding block and configured to movably extend through the second through hole.
